(19) United States
(12) Patent Application Publication
(10) Pub. No.: US 2004/0023505 A1
(43) Pub. Date: Feb. 5, 2004

(54) Method of removing ALF defects after pad etching process

(76) Inventors: Yen-Huei Su, Shioushuei Shiang (TW); Ching-Ping Wu, Taipei (TW); H.W. Lee, Feng-Shan City (TW); Nan-Tzu Lian, Hsinchu (TW); Hsin-Cheng Liu, Hsinchu (TW)

Correspondence Address: RABIN & Berdo, PC, 1101 14TH STREET, NW, SUITE 500, WASHINGTON, DC, 20005, US

(21) Appl. No.: 10/442,267

(22) Filed: May 21, 2003

(30) Foreign Application Priority Data
Aug. 5, 2002 (TW) 91117579

(51) Int. Cl. H01L 21/302; H01L 21/461

(52) U.S. Cl. 438/709

(57) ABSTRACT

A method of removing ALF defects on a device after pad etching process, comprising the steps of: (a) applying EKC solution substantially comprising hydroxylamine (HDA) to the device for about 30 min; (b) applying an intermediate rinse chemical, such as Isopropyl alcohol (IPA) or N-methyl pyrrolidone (NMP), to the device for about 0.5 min to 3 min; and (c) applying water to the device. The ALF defects are effectively removed in the method of the invention, and the bad wafers can be turned to the good ones. Consequently, the primary cost during the manufacture is greatly decreased.

This application claims the benefit of Taiwan application Serial No. 091117579, filed on Aug. 5, 2002.

### BACKGROUND OF THE INVENTION

1. Field of the Invention

The invention relates in general to a method of removing ALF defects after pad etching process, and more particularly to the method of utilizing the rinse chemicals to remove ALF defects after pad etching process.

2. Description of the Related Art

In the manufacture of the semiconductor devices, fluorocarbon plasma such as CF₄ or the combination of CF₄ and CHF₃, is common applied in the pad etching process. During the pad etching process, the unstripped photo-resist (PR) is bombarded by the charged ion, F− so that the surface of PR consequently become rough and traps large amounts of F− ions.

Since the wafers with the semiconductor devices formed thereon are preserved in the pods and each pod is for the storage of about 25 wafers, the F− ions diffused from each wafer cause the high F− concentration in the pod. Consequently, some of F− ions are going to react with the bared aluminum layer and forms the undesired compound of aluminum fluoride (ALF) on the surface of aluminum layer.

The device with undesired ALF is further observed under a scanning electron microscopy (SEM), and the SEM results shows that ALF with the sheet-like crystal appear in irregular shape and some of ALF even have the rolled-up edges. The ALF defects can cause dramatic effect on the post manufacture of semiconductor device, such as bonding fail of golden balls or aluminum balls, as known in the art. Conventionally, those wafers, which have too much semiconductor devices failing in the bonding test, are discarded and no longer usable. Therefore, the production cost is greatly increased. The manufacturers have been suffered no small amount of damage for a long time.

According to the description above, it is the important concern for the manufacturers that how to decrease the production cost by saving the semiconductor devices with ALF defect from discarding.

### SUMMARY OF THE INVENTION

It is therefore an object of the invention to provide a method of removing ALF defects on a device after pad etching process, so that the ALF defects are effectively removed from the surface of the Al layer, and the primary cost during the manufacture is consequently decreased.

The invention achieves the above-identified objects by providing a method of removing ALF defects on a device after pad etching process, comprising the steps of: (a) applying EKC solution substantially comprising hydroxylamine (HDA) to the device for about 30 min; (b) applying an intermediate rinse chemical, such as Isopropyl alcohol (IPA) or N-methyl pyrrolidone (NMP), to the device for about 0.5 min to 3 min; and (c) applying water to the device.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1 is the sectional drawing of a flash memory substrate on which a dielectric layer and a patterned PR have been formed.

### DETAILED DESCRIPTION OF THE INVENTION

At some point during the wet chemical process (for metal etching or post etch residue removal, etc.) of the semiconductor industry, the material have to go through a rinse step, or post clean treatment step. Such rinse steps are designed to remove the chemicals applied in the previous steps and stop any further chemical effects from the previous chemicals. Rinses are generally a three-part system. The first bath contains EKC solution sold by EKC Technology, Inc., Hayward, Calif. EKC solution, an amine-based stripper, substantially comprises hydroxylamine (HDA), organic solvent, corrosion inhibitor, and water. The second bath contains an intermediate rinse chemical, which can be isopropyl alcohol (IPA) or N-methyl pyrrolidone (NMP), to dilute the amine-based EKC solution, followed by a water rinse. This common rinse step and the rinse time can be simply written as:

EKC solution(30 min)→IPA(10 min)water (1)

It has been known that HDA contained in EKC solution can be decomposed by reaction with water, and one of the products is a strong oxidant that can cause serious Al loss of the metallic layer. Although using the admixture of HDA and water as a rinse solution is dangerous and harmful to the semiconductor device, this idea is applied in the invention to solve the ALF defect after pad etching process.

In the invention, the conventional process (1) is modified by decreasing the rinsing time of IPA (or NMP), and applied after pad etching process. The amount of EKC solution remained on the semiconductor device and reacted with water is increased, so that the ALF defects can be ripped off by the etching effect. However, the semiconductor devices that the ALF defects formed thereon are removed have to pass the performance tests to make sure they can work.

IPA cannot be applied in megasonic function due to safety concern. NMP with equivalent low viscosity compared to IPA and with higher flash point (92° C.) than IPA (23° C.) is a better choice. For safety concern, IPA must be replaced by NMP as intermediate rinse solvent when turning on megasonic function. The rinsing time of intermediate rinse chemical, such as IPA or NMP, used in the method of the invention is in the range of about 0.5 min to 3 min, and preferably in the range of about 1 min to 1.5 min. Accordingly, the process of the invention can be written as:

EKC solution(30 min)→IPA or NMP(0.5˜3 min)water (2)

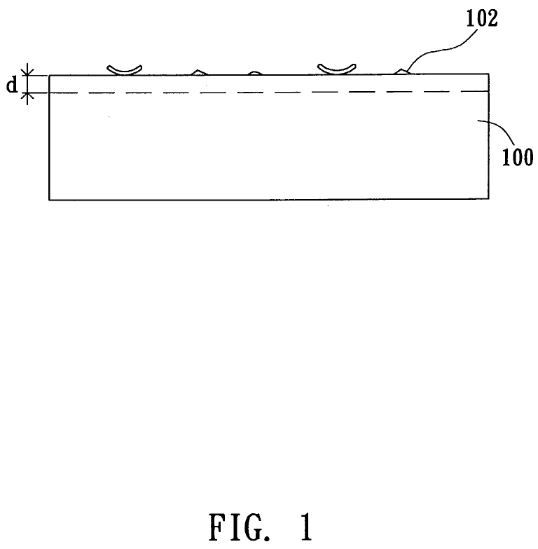

FIG. 1 is a cross-sectional drawing of the Al layer of the semiconductor device after pad etching process. FIG. 1 representing sectional portions of the semiconductor device during fabrication are not drawn to scale, but instead are drawn so as to illustrate the important features of the invention. In FIG. 1, the ALF defects 102, having irregular appearance even the rolled-up edges, are formed on the top surface of the Al layer 100 due to the reaction of AL and F ion. Some amounts of Al are scrapped off by using the method of the invention, and the ALF defects 102 are removed along with the AL loss.

The Al loss of the invention is about 250 Å (d=0.25 K) if the rinsing time of IPA is about 1 min. The conventional Al loss is only about 5 Å if the rinsing time of IPA is about 10 min. Generally, the Al layer of the semiconductor device with a single metallic layer and multilevel interconnects is about 5 K thick and 7-8 K thick, respectively. Compared to 5 K or 8K, 0.25K of Al loss in the invention can be tolerant, and has a good chance to rip off all the ALF defects.

After semiconductor device undergoes the process of the invention, the Quality Check (QC) has to be performed. The semiconductor device is inspected by eyes and by a scanning electron microscopy (SEM) to examine if any ALF defect remains on the surface of Al layer and any EKC residue attacks the Al layer. The results show that almost 100% of AL defects are removed and no serious corrosion occurs on the AL layer.

After the step of Quality Check, the electrical characteristics of the semiconductor device are tested, and the result shows it is normal. Also, the yield test is carried out and the compatible result is shown. The other tests for device performance, such as the bondability tests and reliability tests, are further required. For example, the bondability tests examine the wire pull and ball shear conditions. The reliability tests include the PCT test and the bake test. The results show that the devices of the invention do pass those tests.

According to the aforementioned description, the process (2) of the invention can be applied after pad etching process. It does effectively rip off the ALF defects without causing corrosion and doing harmful to the Al layer. The defective wafer has been turned to a good one by using the process of the invention; therefore, the manufacturer can save large amounts of money and the primary cost is greatly decreased.

While the invention has been described by ways of example and in terms of the preferred embodiment, it is to be understood that the invention is not limited to the disclosed embodiment. To the contrary, it is intended to cover various modifications and similar arrangements and procedures, and the scope of the appended claims therefore should be accorded the broadest interpretation so as to encompass all such modifications and similar arrangements and procedures.

What is claimed is:

1. A method of removing ALF defects on a device after pad etching process, comprising the steps of:
applying EKC solution substantially comprising hydroxylamine (HDA) to the device for about 30 min;
applying an intermediate rinse chemical to the device, wherein a time of applying the intermediate rinse chemical is ranged from 0.5 min to 3 min; and
applying water to the device.

2. The method of removing ALF defects according to claim 1, wherein the intermediate rinse chemical is isopropyl alcohol (IPA).

3. The method of removing ALF defects according to claim 1, wherein the intermediate rinse chemical is N-methyl pyrrolidone (NMP).

4. The method of removing ALF defects according to claim 1, wherein the time for applying the intermediate rinse chemical is ranged from about 1 min to 1.5 min.

5. The method of removing ALF defects according to claim 1, wherein EKC solution further comprises amine base, organic solvent, inhibitor, and water.

6. A method of removing ALF defects on a device after pad etching process, comprising the steps of:
applying EKC solution substantially comprising hydroxylamine (HDA) to the device for about 30 min;
applying an intermediate rinse chemical to the device for about 1 min; and
applying water to the device.

7. The method of removing ALF defects according to claim 6, wherein the intermediate rinse chemical is isopropyl alcohol (IPA).

8. The method of removing ALF defects according to claim 6, wherein the intermediate rinse chemical is N-methyl pyrrolidone (NMP).
